(19) United States
(12) Patent Application Publication
(10) Pub. No.: US 2024/0379886 A1
(43) Pub. Date: Nov. 14, 2024

(54) LIGHTWEIGHT PHOTOVOLTAIC MODULE INCLUDING A GLASS AND POLYMER FRONT LAYER

(71) Applicant: COMMISSARIAT À L'ÉNERGIE ATOMIQUE ET AUX ÉNERGIES ALTERNATIVES, Paris (FR)

(72) Inventors: Julien GAUME, GRENOBLE (FR); Jérôme FRANCOIS, GRENOBLE (FR); Benjamin COMMAULT, GRENOBLE (FR); Bertrand CHAMBION, GRENOBLE (FR); Yannick VESCHETTI, GRENOBLE (FR)

(21) Appl. No.: 18/691,790

(22) PCT Filed: Sep. 12, 2022
(86) PCT No.: PCT/FR2022/051713

§ 371 Date: Mar. 13, 2024

(30) Foreign Application Priority Data
Sep. 14, 2021 (FR) 2109635

(51) Int. Cl. H01L 31/048; H01L 31/18

(52) U.S. Cl. CPC H01L 31/048; H01L 31/18

(57) ABSTRACT

A photovoltaic module obtained from a stack includes: a first transparent layer forming the front face; a plurality of photovoltaic cells; an assembly encapsulating the plurality of cells; and a second layer forming the rear face. The first layer includes: a front layer made of at least one polymer material; at least one front assembly comprising an interface front layer and a glass front layer, with a thickness smaller than or equal to 2 mm, the at least one front assembly being located between the polymer front layer and the encapsulating assembly, and the interface front layer of the at least one front assembly being located between the polymer front layer and the glass front layer.

### TECHNICAL FIELD

The present invention relates to the field of photovoltaic modules, which include a set of photovoltaic cells electrically connected to one another, and preferably so-called “crystalline” photovoltaic cells, i.e. which are based on monocrystalline or multicrystalline silicon.

The invention may be implemented for numerous applications, in particular civil and/or military applications, for example standalone and/or on-board applications, in particular the applications that require the use of lightweight and rigid photovoltaic modules, in particular with a weight per unit area lower than 5 kg/m², and possibly 6 kg/m². Thus, it may in particular be applied for buildings such as homes or industrial premises (tertiary, commercial, etc.), for example to make their roofs, for the design of street furniture, for example for public lighting, road signs or recharging electric cars, and also possibly be used for nomadic applications (solar mobility), in particular for integration on vehicles, such as cars, buses or boats, inter alia.

Thus, the invention provides a lightweight photovoltaic module obtained by a stack including a first glass and a polymer layer forming the front face of the module, as well as a method for producing such a photovoltaic module.

### PRIOR ART

A photovoltaic module is an assembly of photovoltaic cells arranged side-by-side between a transparent first layer forming a front face of the photovoltaic module and a second layer forming a rear face of the module photovoltaic.

Advantageously, the first layer forming the front face of the photovoltaic module is transparent to let the photovoltaic cells receive a luminous flux. It is conventionally made out of one single glass plate, in particular tempered glass, having a thickness typically comprised between 2 and 4 mm, conventionally in the range of 3 mm.

In turn, the second layer forming the rear face of the photovoltaic module may be made of glass, metal or plastic, inter alia. It is often formed by a polymeric structure based on an electrically-insulating polymer, for example of the polyethylene terephthalate (PET) or polyamide (PA) type, which could be protected by one or more layer(s) based on fluorinated polymers, like polyvinyl fluoride (PVF) or polyvinylidene fluoride (PVDF), and having a thickness in the range of 300 μm.

The photovoltaic cells may be electrically connected to one another by front and rear electrical contact elements, so-called connecting conductors, and formed for example by tinned copper strips, respectively arranged against the front faces (the faces lying opposite the front face of the photovoltaic module intended to receive a luminous flux) and rear faces (the faces lying opposite the rear face of the photovoltaic module) of each of the photovoltaic cells, or only at the rear face for the IBC type photovoltaic cells (standing for “Interdigitated Back Contact” in English).

It should be noted that the IBC type photovoltaic cells (“Interdigitated Back Contact”) are structures for which the contacts are made at the rear face of the cell in the form of interdigitated combs. For example, they are described in the American patent U.S. Pat. No. 4,478,879 A.

Moreover, the photovoltaic cells, located between the first and second layers respectively forming the front and rear faces of the photovoltaic module, may be encapsulated. Conventionally, the selected encapsulant corresponds to a polymer of the elastomer (or rubber) type, and may for example consist in the use of two layers (or films) of poly (ethylene-vinyl acetate) (EVA) between which the photovoltaic cells and the connecting conductors of the cells are arranged. Each encapsulant layer may have a thickness of at least 0.2 mm and a Young's modulus typically comprised between 2 and 400 MPa at room temperature.

Thus, a conventional example of a photovoltaic module 1 including crystalline photovoltaic cells 4 has been illustrated partially and schematically, respectively in section in FIG. 1 and in an exploded view in FIG. 2.

As described before, the photovoltaic module 1 includes a front face 2, generally made of transparent tempered glass with a thickness of about 3 mm, and a rear face 5, for example formed by a polymer sheet, opaque or transparent, single-layer or multilayer, having a Young's modulus higher than 400 MPa at room temperature.

The photovoltaic cells 4, electrically connected together by connecting conductors 6 and immersed between two front 3a and rear 3b layers of encapsulation material both forming an encapsulating assembly 3 are located between the front 2 and rear 5 faces of the photovoltaic module 1.

FIG. 1A also shows a variant embodiment of the example of FIG. 1 in which the photovoltaic cells 4 are of the IBC type, the connecting conductors 6 being arranged only against the rear faces of the photovoltaic cells 4.

Moreover, FIGS. 1 and 2 also show the junction box 7 of the photovoltaic module 1, intended to receive the wiring necessary for the operation of the module. Conventionally, this junction box 7 is made of plastic or rubber, and ensures complete sealing.

Usually, the method for making the photovoltaic module 1 includes a so-called lamination step of laminating under vacuum the different layers described before, at a temperature higher than or equal to 120° C., and possibly 140° C., and possibly 150° C., and lower than or equal to 170° C., typically comprised between 145 and 165° C., and for a duration of the lamination cycle generally lasting at least 10 minutes, and possibly 15 minutes.

During this lamination step, the layers of encapsulation material 3a and 3b melt down and embed the photovoltaic cells 4, at the same time as adhesion is created at all interfaces between the layers, namely between the front face 2 and the front layer of encapsulation material 3a, the front layer of encapsulation material 3a and the front faces 4a of the photovoltaic cells 4, the rear faces 4b of the photovoltaic cells 4 and the rear layer of encapsulation material 3b, and the rear layer of encapsulation material 3b and the rear face 5 of the photovoltaic module 1. Afterwards, the obtained photovoltaic module 1 is framed, typically by means of an aluminium profile.

Such a structure has become a standard which has a high mechanical strength thanks to the use of a front face 2 made of thick glass and of the aluminium frame, enabling it, in particular and in most cases, to comply with the standards IEC 61215 and IEC 61730.

Nevertheless, such a photovoltaic module 1 according to the conventional design of the prior art has the drawback of having a relatively high weight, in particular a weight per unit area of about 10 to 12 kg/m², and thus is not suitable for some applications for which lightweight is a priority.

This large weight of the photovoltaic module 1 originates primarily from the presence of the thick glass, with a thickness of about 3 mm, to form the front face 2, the density of the glass actually being high, in the range of 2, 5 kg/m²/mm of thickness, and of the aluminium frame. In order to be able to withstand the stresses during manufacture and also for safety reasons, for example due to the risk of cut-off, the glass is tempered. Yet, the industrial infrastructure of thermal tempering is configured to treat glass that is at least 2 mm thick. Furthermore, the choice of having a glass thickness of about 3 mm is also related to a mechanical strength at the standard pressure of 5.4 kPa. In fine, the glass thus represents on its own substantially 70% of the weight of the photovoltaic module 1, and more than 80% with the aluminium frame around the photovoltaic module 1.

Thus, in order to obtain a significant reduction in the weight of a photovoltaic module to enable use thereof in applications demanding in terms of lightweight, for example commercial roofs, there is a need to find an alternative solution to the use of a thick glass at the front face of the module.

One possibility consists in replacing the glass front face with plastic materials while preserving the usual architecture and implementation method primarily in order to reduce the large surface weight. Thus, sheets of polymers, such as polycarbonate (PC), polyethylene terephthalate (PET), polymethyl methacrylate (PMMA), polyvinylidene fluoride (PVDF), ethylene tetrafluoroethylene (ETFE), ethylene chlorotrifluoroethylene (ECTFE), or fluorinated ethylene propylene (FEP), could be an alternative to glass. However, when only the replacement of the glass by such a thin sheet of polymers is considered, the photovoltaic cell becomes very vulnerable to impact, to mechanical loads and to differential expansions.

One alternative is the use of composite materials, in particular reinforcements, for example glass fibres, carbon fibres or natural fibres such as flax, hemp, inter alia, which complement the standard encapsulant in order to form a polymer/fibre composite associated with a polymer protective film at the front face. The weight saving may be significantly important in spite of less transparency and uncertainty in performance aspects over durations longer than 20 years.

The elimination of glass at the front face of the photovoltaic modules has been the subject-matter of several patents or patent applications in the prior art. In this respect, mention may thus be made of the patent application FR 2 955 051 A1, the American patent application US 2005/0178428 A1 or the international applications WO 2008/019229 A2 and WO 2012/140585 A1. Other patents or patent applications have described the use of reinforcements alone or in composites, like for example the European patent application EP 2 863 443 A1, or the international applications WO 2018/076525 A1, WO 2019/006764 A1 and WO 2019/006765 A1.

### DISCLOSURE OF THE INVENTION

Thus, there is a need to design an alternative photovoltaic module solution intended to be lightweight in order to adapt to some applications, while having sufficient mechanical properties enabling it to be resistant to impacts and to mechanical load, and in particular to the standards IEC 61215 and IEC 61730.

Hence, the invention aims to at least partially address the aforementioned needs and the drawbacks relating to the embodiments of the prior art.

Thus, an object of the invention, according to one of its aspects, is a photovoltaic module obtained from a stack including:
a transparent first layer forming the front face of the photovoltaic module, intended to receive a luminous flux,
a plurality of photovoltaic cells arranged side-by-side and electrically connected to one another,
an assembly encapsulating the plurality of photovoltaic cells,
a second layer forming the rear face of the photovoltaic module, the encapsulating assembly and the plurality of photovoltaic cells being located between the first and second layers,
characterised in that the first layer includes:
a front layer made of at least one polymer material, so-called “polymer front layer”, and
at least one front assembly comprising an interface front layer and a glass front layer, the glass front layer having a thickness smaller than or equal to 2 mm, and possibly 700 μm,
said at least one front assembly being located between the polymer front layer and the encapsulating assembly, and the interface front layer of said at least one front assembly being located between the polymer front layer and the glass front layer.

Advantageously, the invention enables the replacement of standard thick glass with a thickness of about 3 mm, commonly used at the front face in a conventional photovoltaic module, by a combination of polymer layer(s) and thin glass layer(s). Thus, the use of thin glass(s) and polymer(s) allows obtaining a low mass and a transparency equivalent to a standard module. If the invention is compared with the lightweight modules available on the market, the presence of thin glass in the structure allows for a better resistance to impacts, thermomechanical expansions and moisture penetration.

Still advantageously, the use of an encapsulation material of the polymer type with reinforced mechanical properties, in particular for the rear layer of encapsulation material, of the encapsulating assembly could allow further improving the resistance to impacts, in particular of the hail type, on the photovoltaic module, and protecting the photovoltaic cells from possible mechanical damages.

The term “transparent” means that the first layer forming the front face of the photovoltaic module is at least partially transparent to visible light, letting at least about 80% of this light to pass.

In particular, the optical transparency, between 300 and 1,200 nm, of the first layer forming the front face of the photovoltaic module, in particular the polymer front layer, may be higher than 80%. Similarly, the optical transparency, between 300 and 1,200 nm, of the encapsulating assembly may be higher than 90%, just like that of the interface front layer.

Furthermore, by the term “encapsulating” or “encapsulated”, it should be understood that the plurality of photovoltaic cells is arranged within a volume, for example hermetically sealed from liquids, at least partially formed by at least two layers of encapsulation material(s), joined together after lamination to form the encapsulating assembly.

Indeed, initially, i.e. before any lamination operation, the encapsulating assembly consists of at least two layers of encapsulation material(s), so-called core layers, between which the plurality of photovoltaic cells is encapsulated. Nonetheless, during the operation of laminating the layers, the layers of encapsulation material melt down to form, after the lamination operation, one single solidified layer (or assembly) within which the photovoltaic cells are embedded.

Moreover, thanks to the invention, it could be possible to obtain a new type of lightweight photovoltaic modules which, through the use of thin glass, may have a surface weight lower than 6 kg/m², and possibly 5 kg/m², while preserving the optical transparency of the front face and ensuring good reliability of the photovoltaic module with low thermomechanical expansion and high durability. In addition, the use of the polymer front layer and of interface layer(s) allows protecting the thin glass from impacts, in particular of the hail type.

The photovoltaic module according to the invention may further include one or more of the following features considered separately or according to any technically-feasible combination.

Advantageously, the glass front layer may have a thickness smaller than or equal to 1.5 mm, preferably comprised between 500 μm and 1.1 mm, preferably between 500 μm and 1 mm. In a particular embodiment, the glass front layer may also have a thickness comprised between 300 μm and 700 μm, in particular between 300 μm and 500 μm.

Moreover, the glass front layer may advantageously be made of untempered glass. An untempered glass is a glass that has not undergone a post-manufacture chemical or chemical treatment in order to harden it, unlike a so-called tempered glass. In other words, the glass undergoes no thermal or chemical tempering. Indeed, the untempered glass may be less resistant to impacts, in particular those related to the impacts of hail. However, being placed between polymer protective layers, in particular between the polymer front layer and the interface front layer, the untempered glass can be protected from impacts. The untempered glass could also allow ensuring a moisture protection barrier for the photovoltaic cells. The use of untempered glass, rather than tempered glass, could allow considerably reducing the costs so as to make the photovoltaic module adaptable to numerous applications.

The photovoltaic module may also include an adhesion layer, for example in the form of a film, located between the second layer and the rear layer of encapsulation material. The adhesion layer could promote adhesion between the second layer and the encapsulating assembly. The adhesion layer may have a thickness comprised between 20 μm and 100 μm. A plasma-type chemical or physical treatment may be used to clean the surface of the second layer in order to promote adhesion with the adhesion layer.

The second layer may be formed by a conventional rear face, also so-called “backsheet” in English. In particular, the second layer may be formed by a polymeric structure based on an electrically-insulating polymer. In particular, it may be made of at least one polymer material, selected in particular from among: polycarbonate (PC), polymethyl methacrylate (PMMA), polyethylene terephthalate (PET), polypropylene (PP), polyamide (PA), a fluorinated polymer, in particular polyvinyl fluoride (PVF) or polyvinylidene fluoride (PVDF), ethylene tetrafluoroethylene (ETFE), ethylene chlorotrifluoroethylene (ECTFE), polytetrafluoroethylene (PTFE), polychlorotrifluoroethylene (PCTFE), fluorinated ethylene propylene (FEP) and/or a multilayer film comprising one or more of the aforementioned polymers, inter alia.

In the case of a second layer in the form of a polymer multilayer, one or more aluminium layer(s) may be located in the multilayer, while being sandwiched in the latter.

The choice of a second layer made of at least one polymer material may be preferred in the case where the final application of the photovoltaic module requires a superimposition of the latter over a rigid support.

Furthermore, the removal of the thick glass at the front face of the conventional photovoltaic module could induce a loss of mechanical strength of the module. Also, in order to be able to preserve a rigid module, the rear face of the module may be provided to have enough mechanical rigidity.

In particular, according to a first possibility, the second layer may thus include:
a rear layer forming a rear panel made of a composite material, comprising a main sub-layer, forming the core of the rear panel, and two covering sub-layers, each forming a plate of the rear panel, arranged on either side of the core so that the core is sandwiched between the two plates, the core of the rear panel including a cellular structure.

The use of a rear face of the composite sandwich panel type could enable the photovoltaic module according to the invention to have very good mechanical and thermomechanical properties while preserving a low weight.

The core of the rear panel may include a cellular structure, for example in the form of a honeycomb, in particular made of a metal, for example aluminium, of polyimide, of polycarbonate (PC), of polypropylene (PP) or of high-performance synthetic fibres, for example of the Nomex® type.

Alternatively, the core of the rear panel may include a cellular structure in the form of a foam, in particular made of polyethylene terephthalate (PET), polyvinyl chloride (PVC) or polyurethane (PU).

Furthermore, the plates of the rear panel may be made of a composite material, for example of the glass fibre/epoxy prepreg type, of a metal, in particular aluminium, of polycarbonate (PC), of polymethyl methacrylate (PMMA) or from prepregs.

Where appropriate, the plates of the rear panel may be covered with a polymer single-layer or multilayer film, for example of the Tedlar® type.

In addition, the rear panel may have a surface weight lower than or equal to 3 kg/m², in particular lower than or equal to 2 kg/m², still in particular lower than or equal to 1 kg/m².

It should be noted that, rather than having a rear face of the sandwich panel type, the second layer may also include a rear layer including a cellular structure, without the use of covering sub-layers, for example a cellular structure of the cellular polycarbonate type.

According to a second possibility, the second layer may include:
a rear layer made of at least one polymer material, so-called “polymer rear layer”, and
at least one rear assembly comprising an interface rear layer and a glass rear layer, the glass rear layer having in particular a thickness smaller than or equal to 2 mm, even more preferably smaller than or equal to 1.5 mm, and possibly comprised between 500 μm and 1.1 mm, and possibly comprised between 500 μm and 1 mm, and possibly comprised between 300 μm and 700 μm, and possibly between 300 μm and 500 μm, in particular made of untempered glass, and having in particular dimensions strictly smaller than those of the polymer rear layer and in particular the same dimensions and characteristics as those of the glass front layer,
said at least one rear assembly being located between the polymer rear layer and the encapsulating assembly, and the interface rear layer of said at least one rear assembly being located between the polymer rear layer and the glass rear layer.

Thus, the second layer may be obtained according to a principle similar to that used for the first layer. In particular, the second layer may also include a combination of thin glass(s) and polymer(s). The second layer may be identical, or not, to the first layer.

According to a third possibility, the second layer may include a layer of reinforcing fibres based on fibres.

By “layer of reinforcing fibres based on fibres”, it should be understood a layer predominantly including organic and/or inorganic fibres, and preferably a layer consisting of organic and/or inorganic fibres. Advantageously, a layer of reinforcing fibres based on fibres enables mechanical reinforcement of the stack of layers intended to form the photovoltaic module. Before lamination, the fibres of a layer of reinforcing fibres based on fibres are preferably not impregnated, in particular by a polymer material. Such a layer of reinforcements may be so-called fibered, woven or not “dry”. In particular, such a reinforcing layer is neither a prepreg layer, nor a composite layer.

The layer of reinforcing fibres based on fibres may include woven or non-woven fibres. It may also have a weight per unit area comprised between 20 g/m² and 1,500 g/m², and preferably between 300 g/m² and 800 g/m². It may include glass, carbon, aramid fibres and/or natural, in particular hemp, flax and/or silk, fibres, inter alia.

In particular, the glass used for the glass front layer and/or the glass rear layer may consist of soda-lime glass, based on silica, calcium and sodium.

In an advantageous manner, applicable to any embodiment according to the invention, the glass front layer may have dimensions, in particular a length and a width, strictly smaller than those of the front layer made of at least one polymer material and those of the second layer. In addition, the distance separating an edge of the glass front layer and an edge of the front layer made of at least one polymer material or an edge of the second layer may be strictly larger than 1 mm.

Advantageously, the front layer made of at least one polymer material and the second layer may have the same dimensions, in particular the length and the width. Still advantageously, all of the layers of the photovoltaic module, except the glass layer(s), may have the same dimensions, in particular the length and the width, these then corresponding to the dimensions of the module, the glass layer(s) then being encapsulated within the module.

Thus, the glass front layer may have dimensions, in particular a length and a width, strictly smaller than those of the photovoltaic module, the distance separating an edge of the glass front layer and an edge of the photovoltaic module being strictly larger than 1 mm, so that the glass front layer is encapsulated within the photovoltaic module.

In particular, the glass front layer and/or the glass rear layer may have dimensions, in particular a length and a width, strictly smaller than the dimensions of the photovoltaic module obtained by the stack, in particular the length and the width.

Still in particular, the area of a surface of the glass front layer and/or of the glass rear layer, defined in a plane transverse to the stacking direction, is strictly smaller than the area of a surface of any other layer of the stack in a plane transverse to the stacking direction, so that the glass front layer and/or the glass rear layer is encapsulated between two layers located on either side of the glass front layer and/or the glass rear layer respectively.

Still in particular, the distance separating an edge of the glass front layer and/or the glass rear layer and an edge of the photovoltaic module obtained from the stack may be strictly larger than 1 mm.

In the particular case of an untempered glass sensitive to breakage in the event of an impact on its edges, having reduced dimensions allows protecting them from impacts, thanks to an encapsulation including at the edges.

Furthermore, the distance between an edge of a glass front layer and/or a glass rear layer and an edge of a photovoltaic cell and/or an edge of a connecting conductor connecting photovoltaic cells, adjacent to the edge of the glass front layer, may be comprised between 0 and 15 mm, preferably in the range of 5 mm.

It should also be noted that the glass front layer and/or the glass rear layer may include one single glass layer or correspond to a glass multilayer. Where appropriate, the two glass front and rear layers may consist of separate glass layers or glass multilayers, which may comprise, or not, the same number of layers in each multilayer. Alternatively, one may be a separate glass layer whereas the other is a glass multilayer.

In particular, the glass front layer may have rounded edges at its corners, in particular with a radius of curvature strictly larger than 1 mm, preferably strictly smaller than 25 mm.

Furthermore, the glass front layer and/or the glass rear layer may have rounded edges at the corners, in particular four rounded edges at the four corners of a square or rectangular shaped layer. Indeed, in mechanical terms, right angles form stress concentrations and are therefore very fragile, especially in the case of untempered glass. Thus, the fillet of the corners could allow reducing the stresses experienced at the corners. The radius of curvature may be strictly larger than 1 mm, preferably 5 mm. The radius of curvature may also be strictly smaller than 25 mm.

In addition, the photovoltaic module obtained from the stack may be totally devoid of a metal frame, in particular made of aluminium. In order to confer mechanical rigidity on the edges and facilitate handling, the stack may include a polymer frame positioned all around the periphery of a glass front layer and/or a glass rear layer.

Such a polymer frame may be added during the manufacture of the module, positioned in contact with a glass layer in the same plane.

In particular, the photovoltaic module may include a polymer frame arranged all around the periphery of the glass front layer, the polymer frame having in particular a width comprised between 5 mm and 50 mm, preferably between 20 mm and 40 mm.

Moreover, the polymer front layer and/or the polymer rear layer may have a thickness comprised between 15 μm and 300 μm, in particular between 20 μm and 50 μm.

In addition, the polymer material of the polymer front layer and/or of the polymer rear layer may be selected from among: polycarbonate (PC), polymethyl methacrylate (PMMA), polyethylene terephthalate (PET), polyamide (PA), a fluorinated polymer, in particular polyvinyl fluoride (PVF) or polyvinylidene fluoride (PVDF), ethylene tetrafluoroethylene (ETFE), ethylene chlorotrifluoroethylene (ECTFE), polytetrafluoroethylene (PTFE), polychlorotrifluoroethylene (PCTFE), fluorinated ethylene propylene (FEP) and/or a multilayer film comprising one or more of the aforementioned polymers, inter alia.

Furthermore, the polymer front layer and/or the polymer rear layer may have a UV cut-off filter (“UV cutoff” in English) comprised between 320 nm and 450 nm, which corresponds to the wavelength for which the transmission rate is equal to 50%. In this manner, the underlying layers may be protected from ageing with ultraviolet (UV) radiations and possibly from hydrolysis, which provides the photovoltaic module with a longer service life.

The interface front layer and/or the interface rear layer may enable bonding between the polymer front layer, respectively the polymer rear layer, and a glass layer, or between two glass layers.

The interface front layer and/or the interface rear layer may have a thickness comprised between 50 μm and 600 μm, preferably between 400 μm and 600 μm, and possibly between 400 μm and 500 μm.

The interface front layer and/or the interface rear layer may have a Young's modulus comprised between 2 and 300 MPa at 25° C., preferably between 100 and 200 MPa at 25° C., and possibly between 2 and 250 MPa at 25° C., and possibly between 10 and 50 Mpa at 25° C., and possibly between 2 and 50 Mpa at 25° C., and possibly between 2 and 20 MPa at 25° C.

The encapsulating assembly may be obtained by the combination of a front layer of encapsulation material and a rear layer of encapsulation material on either side of the photovoltaic cells, advantageously in direct contact with the latter, the front layer of encapsulation material being located between the first layer and the photovoltaic cells.

The front layer of encapsulation material may be formed by at least one layer including at least one polymer type encapsulation material having a Young's modulus at 25° C. strictly lower than 50 MPa.

In addition, the rear layer of encapsulation material may be formed by at least one layer including at least one polymer type encapsulation material having a Young's modulus at 25° C. strictly higher than 150 MPa.

Advantageously, the use of a polymer type encapsulation material with reinforced mechanical properties, in particular for the rear layer of encapsulation material of the encapsulating assembly, it is possible to further improve the resistance to impacts, in particular of the hail type, on the photovoltaic module, and to protect the photovoltaic cells from possible mechanical damages.

The front layer of encapsulation material may be formed by at least one layer including at least one polymer type encapsulation material having a Young's modulus at 25° C. strictly lower than 50 MPa, in particular higher than 2 MPa and strictly lower than 50 MPa, and possibly strictly lower than 20 MPa, in particular comprised between 10 and 20

MPa.

In addition, the rear layer of encapsulation material may be formed by at least one layer including at least one polymer type encapsulation material having a Young's modulus at 25° C. strictly higher than 200 MPa, in particular strictly higher than 200 MPa and lower than 500 MPa, in particular comprised between 250 and 350 MPa.

Moreover, the elongation at break of the front layer of encapsulation material and/or of the rear layer of encapsulation material may advantageously be at least higher than 200%.

The use of a rear layer of an encapsulation material with a high Young's modulus, could allow obtaining an increased resistance to hail-type impacts.

The front layer of encapsulation material may be formed by at least one layer including at least one polymer type encapsulation material selected from among: poly(ethylene vinyl acetate) (EVA), vinyl acetals, such as polyvinylbutyrals (PVB), polyurethanes, silicone elastomers, elastomers based on crosslinked thermoplastic polyolefin based elastomers and/or crosslinked thermoplastic polyolefin (TPO) based elastomers, inter alia.

The rear layer of encapsulation material may be formed by at least one layer including at least one polymer type encapsulation material selected from among: acid copolymers, ionomers, polyvinyl chlorides and/or polyethylenes, inter alia.

Furthermore, the encapsulating assembly, the interface front layer and/or the possible interface rear layer may be formed by at least one layer including at least one polymer type encapsulation material selected from among: copolymers of acids, ionomers, poly(ethylene-vinyl acetate) (EVA), vinyl acetals, such as polyvinylbutyrals (PVB), polyurethanes, polyvinyl chlorides, polyethylenes, such as linear low-density polyethylenes, elastomeric polyolefins of copolymers, copolymers of α-olefins and α-, β-esters of ethylene carboxylic acid, such as ethylene-methyl acrylate copolymers and ethylene-butyl acrylate copolymers, silicone elastomers and/or crosslinked thermoplastic polyolefin based elastomers, inter alia.

Preferably, the encapsulation material of the encapsulating assembly is identical to the material of the interface front layer, and of the possible interface rear layer. In this manner, it could be possible to facilitate the manufacturing process.

According to a particular embodiment, one amongst the front layers of encapsulation material and rear layers of encapsulation material of the encapsulating assembly, in particular the rear layer of encapsulation material, may include an encapsulation material identical to that of the interface front layer, and the other one amongst the front layer of encapsulation material and the rear layer of encapsulation material of the encapsulating assembly, in particular the front layer of encapsulation material may include an encapsulation material different from that of the interface front layer.

The encapsulating assembly may have a thickness comprised between 200 μm and 600 μm, in particular between 400 μm and 600 μm. In addition, the encapsulating assembly may have a Young's modulus comprised between 2 MPa and 400 MPa at 25° C., and possibly between 2 MPa and 200 MPa at 25° C.

In addition, the photovoltaic cells may be selected from among: homojunction or heterojunction photovoltaic cells based on monocrystalline silicon (c-Si) and/or multi-crystalline silicon (mc-Si), and/or IBC type photovoltaic cells, and/or photovoltaic cells comprising at least one material from among amorphous silicon (a-Si), microcrystalline silicon (μC-Si), cadmium telluride (CdTe), copper-indium selenide (CIS), copper-indium/gallium diselenide (CIGS), and perovskites, inter alia.

Moreover, the photovoltaic cells may have a thickness comprised between 1 and 300 μm, in particular between 1 and 200 μm, and advantageously between 70 μm and 160 μm.

The photovoltaic module may further include a junction box, intended to receive the wiring necessary for the operation of the photovoltaic module, which could be positioned at the front face or at the rear face of the module, preferably at the front face.

Furthermore, the spacing between two neighbouring, or consecutive or adjacent, photovoltaic cells may in some configurations be larger than or equal to 1 mm, in particular comprised between 1 mm and 30 mm, and preferably equal to 2 mm. In other configurations, in particular of the “shingle” type according to the English name (or “bardeau” in French), the neighbouring, or consecutive or adjacent, photovoltaic cells may overlap or have a spacing smaller than 1 mm.

According to a particular embodiment, the first layer may include:
a first front assembly comprising an interface front layer and a glass front layer, the glass front layer having a thickness smaller than or equal to 2 mm,
a second front assembly comprising an interface front layer and a glass front layer, the glass front layer having a thickness smaller than or equal to 2 mm,
the first front assembly being located between the polymer front layer and the second front assembly, itself located between the first front assembly and the encapsulating assembly.

The thickness of the glass front layer of the first front assembly and the thickness of the glass front layer of the second front assembly may be identical or different. In particular, the thickness of the glass front layer of the first front assembly may be larger than the thickness of the glass front layer of the second front assembly.

Advantageously, the dimensions of the glass front layer of the first front assembly and the dimensions of the glass front layer of the second front assembly may be identical, and in particular such as those described before for the glass front layer.

Furthermore, the second layer may include:
a rear layer made of at least one polymer material, so-called “polymer rear layer”, and
a first rear assembly comprising an interface rear layer and a glass rear layer, the glass rear layer having in particular a thickness smaller than or equal to 2 mm, in particular smaller than or equal to 1.5 mm, and possibly comprised between 500 μm and 1.1 mm, and possibly comprised between 500 μm and 1 mm, and possibly comprised between 300 μm and 700 μm, and possibly between 300 μm and 500 μm, and being in particular made of untempered glass,
a second rear assembly comprising an interface rear layer and a glass rear layer, the glass rear layer having in particular a thickness smaller than or equal to 2 mm, in particular smaller than or equal to 1.5 mm, and possibly comprised between 500 μm and 1.1 mm, and possibly comprised between 500 μm and 1 mm, and possibly comprised between 300 μm and 700 μm, and possibly between 300 μm and 500 μm, and being in particular made of untempered glass,
said first rear assembly being located between the polymer rear layer and the second rear assembly, itself located between the first rear assembly and the encapsulating assembly.

Advantageously, the dimensions of the glass rear layer of the first rear assembly and the dimensions of the glass rear layer of the second rear assembly may be identical, and in particular such as those described before for the glass front layer.

In addition, an object of the invention is also, according to another one of its aspects, a method for making a photovoltaic module, in particular as defined before, from a stack including:
a transparent first layer forming the front face of the photovoltaic module, intended to receive a luminous flux,
a plurality of photovoltaic cells arranged side-by-side and electrically connected to one another,
an assembly encapsulating the plurality of photovoltaic cells,
a second layer, the encapsulating assembly and the plurality of photovoltaic cells being located between the first and second layers, characterised in that the first layer includes:
   a front layer made of at least one polymer material, so-called “polymer front layer”, and
   at least one front assembly comprising an interface front layer and a glass front layer, the glass front layer having a thickness smaller than or equal to 2 mm,
said at least one front assembly being located between the polymer front layer and the encapsulating assembly, and the interface front layer of said at least one front assembly being located between the polymer front layer and the glass front layer,
and in that the method includes the step of hot lamination under vacuum of the constituent layers of the stack to obtain the photovoltaic module.

In particular, the step of hot lamination under vacuum may be carried out at a temperature higher than or equal to 120° C., and possibly 140° C., and possibly 150° C., and lower than or equal to 170° C., and possibly 180° C., typically comprised between 130° C. and 180° C., and possibly between 145° C. and 165° C., and for a duration of the lamination cycle lasting at least 5 minutes, and possibly 10 minutes, and possibly 15 minutes, in particular comprised between 5 and 20 minutes.

Thus, it is possible to obtain a total encapsulation of the thin glass allowing protecting it from impacts.

Furthermore, another object of the invention is, according to another one of its aspects, the use:
a photovoltaic module as defined before, in particular of the type comprising a sandwich structure at the rear face, namely wherein the second layer includes a rear layer forming a rear panel made of a composite material, comprising a main sub-layer, forming the core of the rear panel, and two covering sub-layers, each forming a plate of the rear panel, arranged on either side of the core so that the core is sandwiched between the two plates, the core of the rear panel including a cellular structure, and
a support for fastening the photovoltaic module comprising at least two support and fastening elements, in particular in the form of rails, spaced apart from each other, and preferably extending substantially parallel to one another, characterised in that it includes the step consisting in positioning the photovoltaic module in contact only with said at least two support and fastening elements and fastening the photovoltaic module.

In the case of a photovoltaic module comprising a conventional second rear layer, of the “backsheet” type, the module is advantageously directly bonded on its support, for example a roof support.

The photovoltaic module and the method for making thereof according to the invention may include any one of the previously disclosed features, considered separately or according to any technically-feasible combination with other features.

### BRIEF DESCRIPTION OF THE DRAWINGS

The invention could be better understood upon reading the following detailed description, of non-limiting examples of implementation thereof, as well as upon examining the figures, schematic and partial, of the appended drawing, wherein:

FIG. 1 shows, in section, a conventional example of a photovoltaic module including crystalline photovoltaic cells,

FIG. 1A shows a variant of the example of FIG. 1 in which the photovoltaic cells are of the IBC type,

FIG. 2 shows, in an exploded view, the photovoltaic module of FIG. 1,

FIG. 3 illustrates, in perspective and in exploded view, a first embodiment of a photovoltaic module in accordance with the invention,

FIG. 3A illustrates, in section, an example of a rear layer used for the photovoltaic module shown in FIG. 3,

FIG. 3B illustrates, according to a top view, a mechanical test configuration, in particular a hail impact test according to the standard IEC 61215, of a photovoltaic module in accordance with the invention,

FIG. 3C illustrates, according to a top perspective view, an example of use of a photovoltaic module in accordance with the invention,

FIG. 3D illustrates, according to a top perspective view, another example of use of a photovoltaic module in accordance with the invention,

FIG. 4 illustrates, in perspective and in exploded view, a second embodiment of a photovoltaic module in accordance with the invention,

FIG. 5 illustrates, in perspective and in exploded view, a third embodiment of a photovoltaic module in accordance with the invention,

FIG. 6 illustrates, in perspective and in exploded view, a fourth embodiment of a photovoltaic module in accordance with the invention,

FIG. 7 is a partial top view of an example of a photovoltaic module illustrating the principle of a glass layer with reduced dimensions compared to those of the photovoltaic module,

FIG. 8 is a top view of an example of a front and/or rear glass layer, including rounded edges at its corners,

FIG. 9A is a partial top view of an example of a photovoltaic module including a glass layer provided with a polymer frame on its periphery, and

FIG. 9B is a partial sectional view of the photovoltaic module of FIG. 9A.

In all of these figures, identical references may designate identical or similar elements.

Moreover, the different parts shown in the figures are not necessarily displayed according to a uniform scale in order to make the figures easier to read.

### DETAILED DISCLOSURE OF PARTICULAR EMBODIMENTS

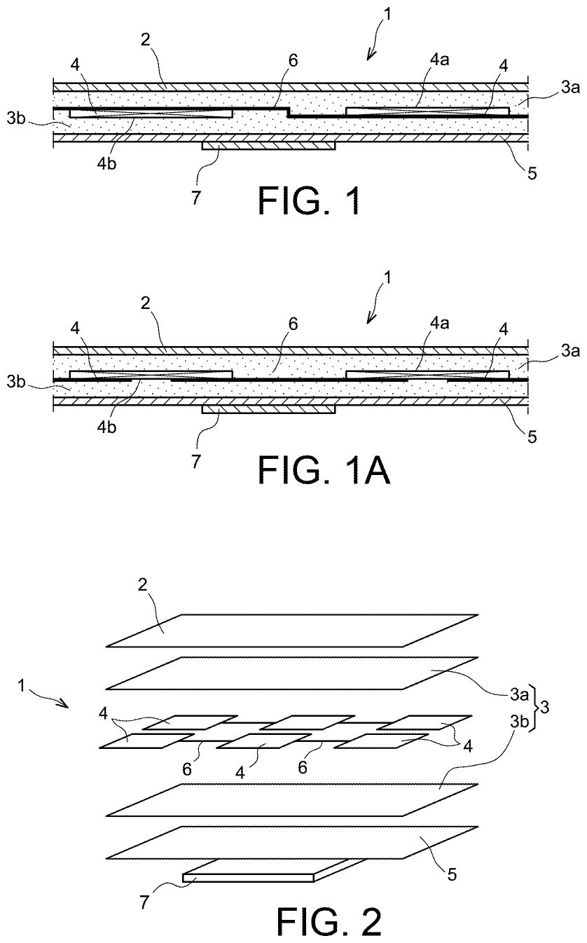

FIGS. 1, 1A and 2 have already been described in the part relating to the prior art.

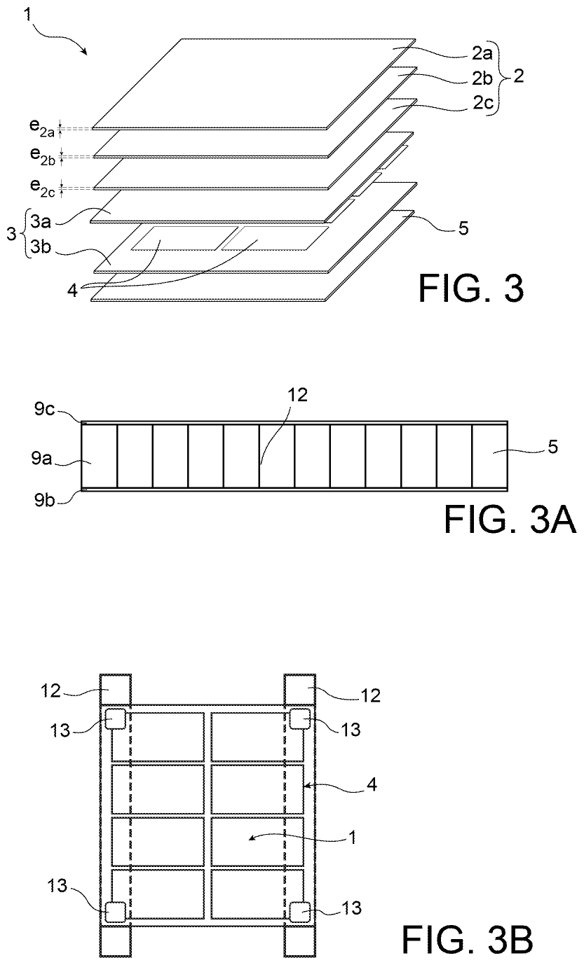

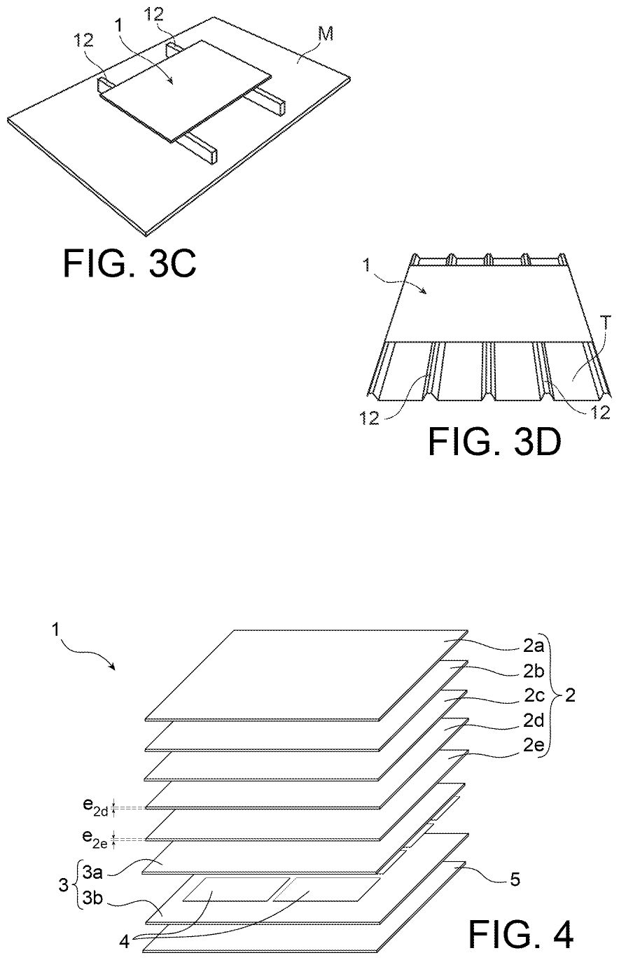

FIGS. 3 to 9B allow illustrating four distinct embodiments of photovoltaic modules 1 in accordance with the invention.

It is herein considered that the photovoltaic cells 4, interconnected by welded tinned copper strips, similar to those shown in FIGS. 1, 1A and 2, are “crystalline” cells, i.e. they include monocrystalline or multicrystalline silicon, and they have a thickness comprised between 1 and 250 μm.

In addition, the polymer front layer 2a may be a fluorinated polymer film, with a thickness in the range of 20 μm, in particular made of ethylene chlorotrifluoroethylene (ECTFE), for example of the Amcor® ECTFE 020 type.

The interface layers 2b, 2d and 5b may include a polymer encapsulant film, for example of the A type formed by a thermoplastic polyolefin-based elastomer (TPO) or of the B type formed by an ionically crosslinked thermoplastic copolymer, for example of the Ionomer type. The thickness may be comprised between 500 and 600 μm. In particular, for a type B polymer encapsulant film, it may consist of KuranSeal-ES® (PV8729D/UV CUT) from the company Kurabo, with a thickness of 500 μm.

The glass layers 2c, 2e and 5c may include an untempered thin glass with a thickness comprised between 500 and 800 μm, for example in the range of 550 μm.

The second layer 5 may be in the form of a polymer layer or multilayer of the “backseet” type or else of a polymeric structure based on an electrically-insulating polymer.

The second layer 5 may also be in the form of a rear panel 5, a “sandwich” type structure, and may include a core 9a made of polypropylene honeycomb and composite skins or plates 9b, 9c made of glass-reinforced polypropylene with a thickness comprised for example between 6 and 10 mm, for example of the Nidapan® 8 GR 600 type with a thickness of 10 mm.

Of course, these choices are in no way restrictive.

For all of the examples of stacking described with reference to FIGS. 3 to 9B, tests have been performed with regards to hail type mechanical impacts for 2J energy levels representative of the IEC 61215 certification standard. The results have demonstrated the fact that the integration of a thin untempered glass into the module allows obtaining a reduced weight while having an impact resistance in accordance with the standards in force.

In particular, in the case of a second layer 5 in the form of a “sandwich”-type rear panel 5, as one could see in FIG. 3A, the mechanical impact tests have been carried out according to the configuration shown in FIG. 3B. Thus, the photovoltaic module 1, for example with a 40 cm×40 cm dimension, has been fastened on two aluminium rails 12 with a thickness of 4 cm. This fastening has been done by means of clamps 13. Outside the contact surface between the photovoltaic module 1 and the aluminium rails 12, the rest of the module 1 has not rested on any other surface.

The results have demonstrated the increased improvement in the impact resistance, in accordance with the current standards, with the use of an untempered thin glass, in the range of 700 μm, in a photovoltaic module 1 in a discontinuous installation configuration.

In order to describe the considered different configurations, reference is first made to FIG. 3 which illustrates, in perspective and in exploded view, a first embodiment of a photovoltaic module 1 in accordance with the invention.

It should be noted that FIG. 3 corresponds to an exploded view of the photovoltaic module 1 before the lamination step of the method according to the invention. Once the lamination step is completed, ensuring hot and pressing under vacuum, the different layers are actually in contact with one another, and in particular interpenetrating inside one another.

Thus, the photovoltaic module 1, or more specifically the stack intended to form the photovoltaic module 1, includes a first layer 2 forming the front face of the photovoltaic module 1 and intended to receive a luminous flux, a plurality of photovoltaic cells 4 arranged side-by-side and electrically connected to one another, an assembly encapsulating 3 the plurality of photovoltaic cells 4, and a second layer 5 forming the rear face of the photovoltaic module 1.

It should also be noted that a junction box 7 may be arranged on the front face or on the rear face, as shown in FIGS. 1, 1A and 2, of the photovoltaic module 1.

In accordance with the invention, and in common with the examples of FIGS. 3 to 6, the first layer 2 includes a front layer made of a polymer material 2a, so-called “polymer front layer 2a”, and a first front assembly 2b, 2c comprising an interface front layer 2b and a glass front layer, advantageously made of untempered glass 2c.

Advantageously, the glass front layer 2c has a thickness e_{2c} smaller than or equal to 2 mm, and possibly smaller than or equal to 1.5 mm, and possibly comprised between 500 μm and 1.1 mm, and possibly comprised between 500 μm and 1 mm, and possibly comprised between 300 μm and 700 μm, and possibly between 300 μm and 500 μm.

In this example, the front encapsulation layer 3a, the rear encapsulation layer 3b and the interface front layer 2b are all of the type A encapsulant film.

In all of the examples described herein with reference to FIGS. 3 to 6, the invention may advantageously provide for having a rear layer of an encapsulation material with a Young's modulus at 25° C. strictly higher than 150 MPa, in particular strictly higher than 200 MPa, preferably strictly higher than 200 MPa, and possibly 150 MPa, and lower than 500 MPa, and possibly comprised between 250 and 350 MPa.

The front layer of encapsulation material 3a may be identical to the rear layer of encapsulation material 3b according to one embodiment. Alternatively, it may be different, in particular with a Young's modulus at 25° C. strictly lower than 50 MPa, preferably higher than 2 MPa and strictly lower than 50 MPa, and possibly comprised between 10 and 20 MPa.

The front layer of encapsulation material 3a may consist of a type A encapsulant film whereas the rear layer of encapsulation material 3b consists of a type B encapsulant film. Alternatively, the front 3a and rear 3b layers may consist of type B encapsulant films.

Thus, through the use of a type B encapsulant film for the rear layer of encapsulation material 3b, rather than the use of a type A encapsulant film, it is possible to limit or completely avoid any phenomenon of breakage of the glass and of the photovoltaic cells 4.

The second layer 5 may be formed by a conventional rear face, also so-called “backsheet” in English, as shown in FIG. 3. In particular, the second layer 5 may be formed by a polymeric structure based on an electrically-insulating polymer. In particular, it may be made of at least one polymer material, in particular selected from among: polycarbonate (PC), polymethyl methacrylate (PMMA), polyethylene terephthalate (PET), polypropylene (PP), polyamide (PA), a fluorinated polymer, in particular polyvinyl fluoride (PVF) or polyvinylidene fluoride (PVDF), ethylene tetrafluoroethylene (ETFE), ethylene chlorotrifluoroethylene (ECTFE), polytetrafluoroethylene (PTFE), polychlorotrifluoroethylene (PCTFE), fluorinated ethylene propylene (FEP) and/or a multilayer film comprising one or more of the aforementioned polymers, inter alia. In the case of a second layer 5 in the form of a polymer multilayer, one or more aluminium layers may be located in the multilayer, sandwiched in the latter.

The second layer 5 may also be in the form of a “sandwich” type structure. For example, the second layer 5 may be formed by a rear panel 5 made of a composite material, comprising a main sub-layer, forming the core 9a of the rear panel 5, and two covering sub-layers, each forming a plate 9b, 9c of the rear panel 5, arranged on either side of the core 9a so that the core 9a is sandwiched between the two plates 9b, 9c, the core 9a of the rear panel 5 including a cellular structure 12. FIG. 3A shows such a second layer 5, schematically in section in a more detailed manner.

It should further be noted that, alternatively, the second layer 5 could include a layer of reinforcements based on fibres, woven or not, in particular glass, carbon, aramid and/or natural fibres, in particular hemp fibres, flax and/or silk, inter alia.

The photovoltaic module 1 is obtained through one single step of hot lamination under vacuum, for example at a temperature of about 150° C. for about 15 minutes. It may have a weight per unit area comprised between 4 and 6 kg/cm², for example in the range of 6 kg/cm² in the case of a “backsheet” type layer 5 and in the range of 4 kg/cm² in the case of a sandwich structure type layer 5.

It is also possible to use type B encapsulant films for the encapsulation front layer 3a, the encapsulation rear layer 3b and the interface front layer 2b. Then, the impact resistance of the photovoltaic module 1 is further improved thanks to a higher Young's modulus.

In the case of a second layer 5 in the form of a sandwich structure, of the type of FIG. 3A, FIGS. 3C and 3D illustrate two examples of configurations of use of such a photovoltaic module 1 in accordance with the invention.

The use of a photovoltaic module 1 in accordance with the invention consists in positioning the module 1 and fastening it on a fastening support M, T which comprises a plurality of support and fastening elements 12, and in particular rails 12 parallel to one another and defining spaces therebetween.

Thus, in the example of FIG. 3C, the panel 5 of the photovoltaic module 1 is not bonded directly to the sealing membrane M, which would result in an absence of separation between the surface of the membrane M and the panel 5. Conversely, rails 12 are positioned on the membrane M, while being spaced apart from one another, and the panel 5 of the photovoltaic module 1 is fastened directly and only in contact with the rails 12.

Moreover, in the example of FIG. 3D, the panel 5 of the photovoltaic module 1 is fastened on the ribs or corrugations, forming rails 12 parallel to one another and spaced apart from each other, of a sheet metal T, for example made of steel. By means of a unique contact on the rails 12 of the sheet metal T, contact with moisture and potential fouling are thus avoided while providing a larger space for positioning the panel 5. Conversely, a flexibility is obtained in the choice of the dimensions of the panel 5 and/or of the sheet metal T, a spacing between the surface of the sheet metal T and the panel 5 and a resistance to hail related to the principle of the invention.

Thus, the invention allows providing a photovoltaic module 1 and a use thereof which are particularly suitable for applications sensitive to overload, in particular roofs, while keeping a separation between the panel 5 and the surface, in particular the roof. For terrace type almost planar roofs, like for the example of FIG. 3C, or inclined roofs, like for the example of FIG. 3D, the invention allows reducing the contact of the module 1 with the surface of the roof, and therefore a limitation of the penetration of moisture or of the freeze and thaw phenomena, so as to protect it and guarantee sealing. The use of existing supports or specific supports may be considered.

Moreover, FIG. 4 illustrates a second embodiment in accordance with the invention.

In this example, unlike that of FIG. 3, the first layer 2 also includes a second front assembly 2d, 2e comprising an interface front layer 2d and a glass front layer, advantageously made of untempered glass 2e. The glass front layer 2e has a thickness e₂ₑ smaller than or equal to 2 mm, and possibly smaller than or equal to 1.5 mm, and possibly comprised between 500 μm and 1.1 mm, and possibly comprised between 500 μm and 1 mm, and possibly comprised between 300 μm and 700 μm, and possibly comprised between 300 μm and 500 μm. In other words, this embodiment provides for doubling the glass thickness in the first layer 2. A photovoltaic module 1 with a surface weight equal to 6 kg/cm² is then obtained. The impact resistance of the photovoltaic module 1 is further improved.

In addition, the first interface front layer 2b and the front 3a and rear 3b encapsulation layers are formed by type A encapsulant films, while the second interface front layer 2d is formed by a type B encapsulant film.

In the example of FIG. 4, the first glass front layer 2b and the second glass front layer 2e have the same thickness. Alternatively, it is possible to use different thicknesses of glass, for example a thickness e2b in the range of 500 μm and a thickness e₂ₑ in the range of 300 μm. Thus, if it is considered that 800 μm of glass could address the need for the impact resistance of the cells 4, it is possible to use for example a 500 μm glass and a 300 μm glass.

Indeed, it is known that the elastomeric materials have vibration and impact-absorbing properties. Thus, the alternation of rigid materials with elastomeric materials will allow modifying the propagation speed of impact waves, because the velocity of an impact wave is directly proportional to the Young's modulus and Poisson's coefficients of the used material. Hence, the insertion of flexible elastomer layers, between layers of more rigid materials, allows slowing down the propagation of impact waves. In addition, at each interface encountered, the impact wave could be partially transmitted and/or reflected. Hence, the repetition of the alternation of these polymer layers having different Young's moduli allows, on the one hand, slowing down the impact waves and, on the other hand, reducing the intensity of the latter which arrive at the photovoltaic cells.

Also, with an equivalent amount of glass, it may be more advantageous to distribute this amount between at least two layers of glass with different thicknesses instead of one single layer of glass.

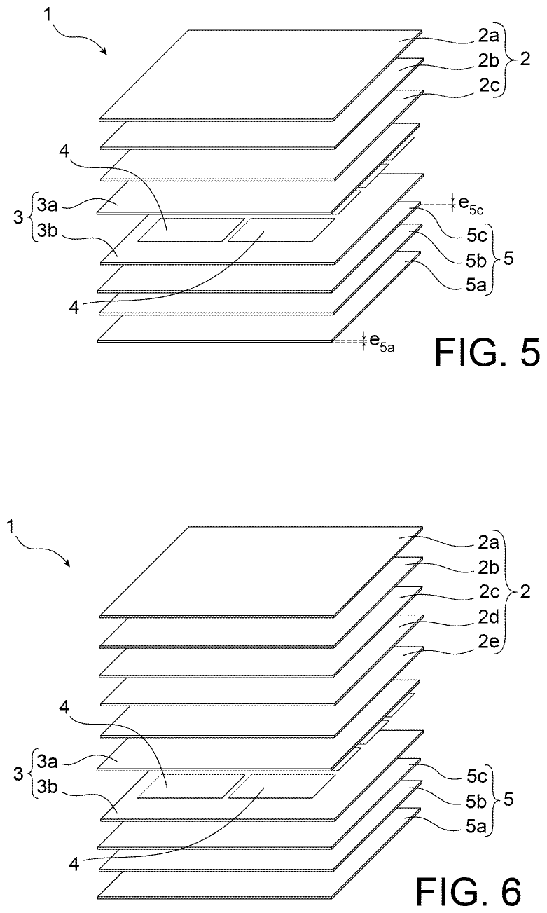

Furthermore, FIG. 5 also illustrates a third embodiment, the principle of which consists in using, at the rear face, the same encapsulation architecture as at the front face, symmetrically. Thus, it is possible to obtain a bifacial and lightweight photovoltaic module 1.

Thus, the second layer 5 herein includes a rear layer made of a polymer material 5 a, so-called “polymer rear layer” 5a, and a first rear assembly 5b, 5c comprising an interface rear layer 5b and a glass rear layer, preferably untempered 5c.

The glass rear layer 5c has a thickness e_{5c} of 550 μm, and the glass front layer 2c also has a thickness e_{2c} of 550 μm.

The interface front layer 2b, the interface rear layer 5b, the front 3a and rear 3b encapsulation layers herein consist of type B encapsulant films.

Furthermore, FIG. 6 illustrates a fourth embodiment corresponding to a variant of the example of FIG. 5 in which the use of thin glasses preferably untempered at the front face and at the rear face is done asymmetrically.

In particular, two thin glasses 2c and 2e may be used at the front face of identical or different thicknesses, and a thin glass 5c may be used at the rear face. More specifically, herein, a first glass front layer 2c has a thickness e_{2c} of 500 μm, a second glass front layer 2e has a thickness e₂ₑ of 300 μm, and a first glass rear layer 5c has a thickness e_{5c} of 550 μm.

In addition, the first interface front layer 2b, the second interface front layer 2d, the interface rear layer 5b, the front 3a and rear 3b encapsulation layers herein consist of type B encapsulant films.

In all of the previously-described examples, the polymer front layer 2a and the polymer rear layer 5a have a thickness e2a, e5a in the range of 20 μm.

The interface front layers 2b, 2d and the interface rear layer 5b have a thickness e2b, e2d, e5b in the range of 600 μm.

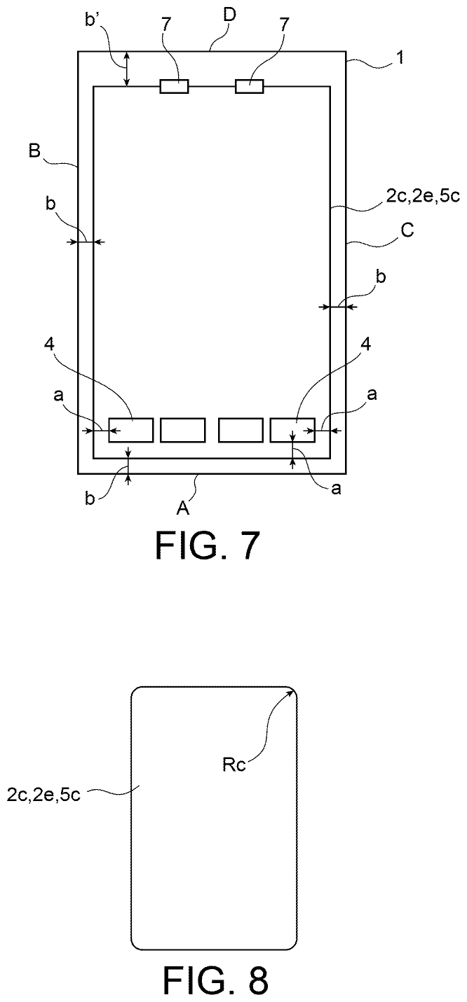

Moreover, FIGS. 7 to 9B illustrate other features of the invention applicable to all of the previously-described examples.

In particular, FIG. 7 illustrates the fact that a glass layer, for example a glass front layer and/or a glass rear layer, herein the front layer 2c or 2e or the rear layer 5c, may have dimensions strictly smaller than the dimensions of the polymer front layer 2a and of the second layer 5, and in particular those of the photovoltaic module 1 obtained by the stack when all of the layers except those made of glass have the same dimensions, namely the same lengths and the same widths.

In particular, the length of such a glass layer is strictly smaller than the length of the module, and the width of such a glass layer is strictly smaller than the width of the module. In other words, the area of the surface of such a glass layer, defined in a plane transverse to the stacking direction, is strictly smaller than the area of a surface of any other layer of the stack in a plane transverse to the stacking direction.

Advantageously, such a glass layer is then encapsulated between two layers located on either side of the latter.

In the particular case of an untempered glass sensitive to breakage in the event of an impact on its edges, the fact of having reduced dimensions thus allows protecting it from impacts, thanks to the total encapsulation of the glass layer, including on the edges.

The dimension of the glass may be characterised by the dimension a representing the distance between the edge of the last conductive element and the edge of the glass, namely herein the distance a between the edge of the cells 4 and the edge of the glass for the sides B and C of the module, and between the edge of the last strip 6 and the edge of the glass for the side A of the module, opposite to the junction boxes 7. This distance a may be comprised between 0 and 15 mm, and preferably in the range of 5 mm.

Moreover, the distance b separating an edge of the glass layer and an edge of the polymer front layer 2a or the second layer 5, in particular of the photovoltaic module 1 when all layers, except the glass layer, have the same dimensions, may be strictly larger than 1 mm, and that being so on the four edges A, B, C and D of the photovoltaic module 1.

Furthermore, for the side D of the module where the junction boxes 7 are present, the glass layer is partially arranged under the junction boxes 7. The overlap may be comprised between 1 and 30 mm, preferably between 1 and 10 mm.

The distance b′ separating the edge of the glass layer 2c, 2e, 5c and the edge of the polymer front layer 2a or the second layer 5, in particular of the photovoltaic module 1 when all layers, except the glass layer, have the same dimensions, may be at least 5 mm, preferably between 25 mm and 50 mm, and possibly in the range of 37 mm.

Moreover, FIG. 8 illustrates the possibility for a glass layer to have rounded edges at the corners, in particular four rounded edges at the four corners of a square or rectangular shaped layer.

Indeed, in mechanical terms, right angles form stress concentrations and are therefore very fragile, especially in the case of untempered glass. Thus, the fillet of the corners could allow reducing the stresses experienced at the corners. The radius of curvature Rc may be strictly larger than 1 mm, preferably 5 mm. The radius of curvature may further be strictly smaller than 25 mm.

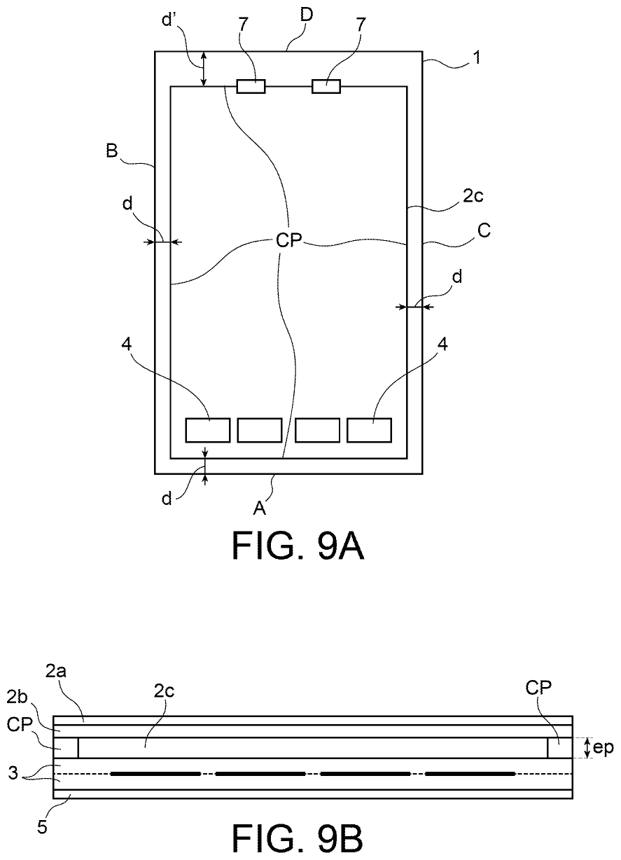

Furthermore, FIGS. 9A and 9B illustrate the principle of adding a polymer frame at one or more glass layer(s) in order to confer rigidity on the module, which is devoid of a conventional aluminium frame.

Indeed, in order to confer mechanical rigidity on the edges and facilitate handling, the stack may include a polymer frame CP positioned all around the periphery of a glass front layer and/or a glass rear layer.

Such a polymer frame CP may be added during the manufacture of the module, positioned in contact with a glass layer in the same plane.

The width d of the polymer frame CP may be comprised between 1 mm and 30 mm, preferably between 10 mm and 25 mm, on the edges A, B and C of the module 1. On the edge D on the side of the junction boxes 7, the width d of the polymer frame CP may be comprised between 1 mm and 50 mm, preferably between 30 mm and 40 mm.

Advantageously, the thickness ep of the polymer frame CP, before the lamination process, is comprised between 0.1 mm and 2 mm, preferably between 0.5 mm and 1 mm. The thermomechanical properties of this polymer frame CP may be identical to those of one of the layers of encapsulation material, for example the rear layer 3b of encapsulation material or one of the interface layers.

Of course, the invention is not limited to the embodiments that have just been described. Various modifications may be made thereto by a person skilled in the art.

In particular, these embodiments may be declined according to various variants using one or more of the aforementioned materials to form the first layer 2 and the second layer 5.

What is claimed is:

1. A photovoltaic module obtained from a stack including:
a transparent first layer forming the front face of the photovoltaic module, intended to receive a luminous flux,
a plurality of photovoltaic cells arranged side-by-side and electrically connected to each other,
an assembly encapsulating the plurality of photovoltaic cells,
a second layer forming the rear face of the photovoltaic module, the encapsulating assembly and the plurality of photovoltaic cells-being located between the first and second layers,
wherein the first layer includes:
a front layer made of at least one polymer material, so-called “polymer front layer”, and
at least one front assembly comprising an interface front layer and a glass front layer, the glass front layer having a thickness (e_{2c}; e₂ₑ) smaller than or equal to 2 mm, and having dimensions strictly smaller than those of the front layer made of at least one polymer material and those of the second layer, the distance (b, b′) separating an edge of the glass front layer and an edge of the front layer made of at least one polymer material or an edge of the second layer being strictly larger than 1 mm, said at least one front assembly being located between the polymer front layer and the encapsulating assembly, and the interface front layer of said at least one front assembly being located between the polymer front layer and the glass front layer.

2. The module according to claim 1, wherein the glass front layer is made of untempered glass.

3. The module according to claim 1, wherein the distance (a) between an edge of the glass front layer and an edge of a photovoltaic cell and/or an edge of a connecting conductor connecting cells photovoltaic, adjacent to the edge of the glass front layer, is comprised between 0 and 15 mm, preferably in the range of 5 mm.

4. The module according to claim 1, further including a polymer frame (CP) arranged all around the perimeter of the glass front layer, the polymer frame (CP) having in particular a width (d, d′) comprised between 5 mm and 50 mm, preferably between 20 mm and 40 mm.

5. The module according to claim 1, wherein the glass front layer has rounded edges at its corners, in particular with a radius of curvature (Rc) strictly larger than 1 mm, preferably strictly smaller than 25 mm.

6. The module according to claim 1, wherein the glass front layer has a thickness (e_{2c}; e₂ₑ) smaller than or equal to 1.5 mm, in particular comprised between 500 μm and 1.1 mm, more particularly comprised between 500 μm and 1 mm, more particularly comprised between 300 μm and 700 μm, more particularly between 300 μm and 500 μm.

7. The module according to claim 1, wherein the second layer is formed by a polymeric structure based on an electrically-insulating polymer.

8. The module according to claim 1, wherein the second layer includes:
a rear layer forming a rear panel made of a composite material, comprising a main sub-layer, forming the core of the rear panel, and two covering sub-layers, each forming a plate of the rear panel, arranged on either side of the core so that the core is sandwiched between the two plates, the core of the rear panel including a cellular structure.

9. The module according to claim 1, wherein the second layer includes:
a rear layer made of at least one polymer material, so-called “polymer rear layer”, and
at least one rear assembly comprising an interface rear layer and a glass rear layer, the glass rear layer having in particular a thickness (esc) smaller than or equal to 2 mm, in particular smaller than or equal to 1.5 mm, in particular comprised between 500 μm and 1.1 mm, more particularly between 500 μm and 1 mm, more particularly between 300 μm and 700 μm, more particularly between 300 μm and 500 μm, being in particular made of untempered glass, and having in particular dimensions strictly smaller than those of the polymer rear layer and in particular the same dimensions and characteristics as those of the glass front layer,
said at least one rear assembly being located between the polymer rear layer and the encapsulating assembly, and the interface rear layer of said at least one rear assembly being located between the polymer rear layer and the glass rear layer.

10. The module according to claim 1, wherein the second layer includes a layer of reinforcing fibres based on fibres, in particular glass, carbon, aramid and/or natural, in particular hemp, flax and/or silk, fibres.

11. The module according to claim 1, wherein the polymer front layer and/or the polymer rear layer have a thickness (e2a, e5a) comprised between 15 μm and 300 μm, in particular between 20 μm and 50 μm.

12. The module according to claim 1, wherein the interface front layer and/or the interface rear layer have a thickness (e2b, e2d; e5b) comprised between 50 μm and 600 μm, in particular between 400 μm and 600 μm, in particular between 400 μm and 500 μm.

13. The module according to claim 1, wherein the polymer material of the polymer front layer and/or of the polymer rear layer is selected from among: polycarbonate (PC), polymethyl methacrylate (PMMA), polyethylene terephthalate (PET), polyamide (PA), a fluoropolymer, in particularpolyvinyl fluoride (PVF) or polyvinylidene fluoride (PVDF), ethylene tetrafluoroethylene (ETFE), ethylene chlorotrifluoroethylene (ECTFE), polytetrafluoroethylene (PTFE), polychlorotrifluoroethylene (PCTFE), fluorinated ethylene propylene (FEP), and/or a multilayer film comprising one or more of the aforementioned polymers.

14. The module according to claim 1, wherein the encapsulating assembly, the interface front layer and/or the optional interface rear layer are formed by at least one layer including at least one polymer type encapsulation material selected from among: acid copolymers, ionomers, poly (ethylene vinyl acetate) (EVA), vinyl acetals, such as polyvinylbutyrals (PVB), polyurethanes, polyvinyl chlorides, polyethylenes, such as linear low-density polyethylenes, elastomeric polyolefins of copolymers, copolymers of α-olefins and α-, β-esters of ethylene carboxylic acid, such as ethylene-methyl acrylate copolymers and ethylene-butyl acrylate copolymers, silicone elastomers and/or crosslinked thermoplastic polyolefin-based elastomers.

15. The module according to claim 1, wherein the first layer includes:
a first front assembly comprising an interface front layer and a glass front layer, the glass front layer having a thickness (e_{2c}) smaller than or equal to 2 mm,
a second front assembly comprising an interface front layer and a glass front layer, the glass front layer having a thickness (e₂ₑ) smaller than or equal to 2 mm,
the first front assembly being located between the polymer front layer and the second front assembly, itself located between the first front assembly and the encapsulating assembly.

16. The module according to claim 15, wherein the thickness (e_{2c}) of the glass front layer of the first front assembly and the thickness (e₂ₑ) of the glass front layer of the second front assembly are different.

17. The module according to claim 16, characterised in that wherein the thickness (e_{2c}) of the glass front layer of the first front assembly is larger than the thickness (e₂ₑ) of the glass front layer of the second front assembly.

18. The module according to claim 1, wherein the second layer includes:
-a rear layer made of at least one polymer material (5a), so-called “polymer rear layer”, and
a first rear assembly comprising an interface rear layer and a glass rear layer, the glass rear layer having in particular a thickness (e_{5c}) smaller than or equal to 2 mm, in particular smaller than or equal to 1.5 mm, in particular comprised between 500 μm and 1.1 mm, more particularly comprised between 500 μm and 1 mm, more particularly comprised between 300 μm and 700 μm, more particularly between 300 μm and 500 μm, and being in particular made of untempered glass,
a second rear assembly comprising an interface rear layer and a glass rear layer, the glass rear layer having in particular a thickness smaller than or equal to 2 mm, in particular smaller than or equal to 1.5 mm, in particular comprised between 500 μm and 1.1 mm, more particularly comprised between 500 μm and 1 mm, more particularly comprised between 300 μm and 700 μm, more particularly between 300 μm and 500 μm, and being in particular made of untempered glass,
said first rear assembly being located between the polymer rear layer and the second rear assembly, itself located between the first rear assembly and the encapsulating assembly.

19. A method for making a photovoltaic module according to claim 1, from a stack including:
-a transparent first layer forming the front face of the photovoltaic module, intended to receive a luminous flux,
a plurality of photovoltaic cells arranged side-by-side and electrically connected to each other,
an assembly encapsulating the plurality of photovoltaic cells,
a second layer, the encapsulating assembly and the plurality of photovoltaic cells being located between the first and second layers,
wherein the first layer includes:
a front layer made of at least one polymer material, so-called “polymer front layer”, and
at least one front assembly comprising an interface front layer and a glass front layer, the glass front layer having a thickness (e_{2c}; e₂ₑ) smaller than or equal to 2 mm, and having dimensions strictly smaller than those of the front layer made of at least one polymer material and those of the second layer, the distance (b, b′) separating an edge of the glass front layer and an edge of the front layer made of at least one polymer material or an edge of the second layer being strictly larger than 1 mm, said at least one front assembly being located between the polymer front layer and the encapsulating assembly, and the interface front layer of said at least one front assembly being located between the polymer front layer and the glass front layer.
